(19) United States
(12) Patent Application Publication
(10) Pub. No.: US 2026/0019091 A1
(43) Pub. Date: Jan. 15, 2026

(54) POLAR SEQUENCE EXTENSIONS FOR WIRELESS COMMUNICATION DEVICES

(71) Applicant: Lenovo (United States) Inc., Morrisville, NC (US)

(72) Inventors: Abir Ben Hadj Fredj, Frankfurt am main (DE); Razvan-Andrei Stoica, Witten (DE); Karthikeyan Ganesan, Kraiburg am Inn (DE)

(21) Appl. No.: 19/330,244

(22) Filed: Sep. 16, 2025

(51) Int. Cl. H03M 13/13

(52) U.S. Cl. CPC H03M 13/134

(57) ABSTRACT

Various aspects of the present disclosure relate to methods, apparatuses, and devices for wireless communication. A transmitting device may determine, based on a first polar sequence of a code having a first length and one or more code parameters, a second polar sequence of the code having a greater length. The transmitting device may further determine, in accordance with a nesting property of the first polar sequence and at least one of the code parameters, a reordering of extension sequence subchannels. The transmitting device may then encode information using the second polar sequence and transmit the encoded information.

### TECHNICAL FIELD

The present disclosure relates to wireless communications, and more specifically to polar sequence extensions in a wireless communications system.

### BACKGROUND

A wireless communications system may include one or multiple network communication devices, which may be known as a network equipment (NE), supporting wireless communications for one or multiple user communication devices, which may be otherwise known as user equipment (UE), or other suitable terminology. The wireless communications system may support wireless communications with one or multiple user communication devices by utilizing resources of the wireless communication system (e.g., time resources (e.g., symbols, slots, subframes, frames, or the like) or frequency resources (e.g., subcarriers, carriers, or the like)). Additionally, the wireless communications system may support wireless communications across various radio access technologies including third generation (3G) radio access technology, fourth generation (4G) radio access technology, fifth generation (5G) radio access technology, among other suitable radio access technologies beyond 5G (e.g., 5G-Advanced (5G-A), sixth generation (6G), etc.).

### SUMMARY

As used herein, including in the claims, an article “a” before an element is unrestricted and understood to refer to “at least one” of those elements or “one or more” of those elements. The terms “a,” “at least one,” “one or more,” and “at least one of one or more” may be interchangeable. As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C means A or B or C or AB or AC or BC or ABC (i.e., A and B and C). Also, as used herein, including in the claims, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.” Further, as used herein, including in the claims, a “set” may include one or more elements.

Various aspects of the present disclosure relate to wireless communications, including polar sequence extensions in a wireless communications system.

A transmitting device for wireless communication is described. The transmitting device may be configured to, capable of, or operable to determine, based on a first polar sequence of a code having a first length and one or more code parameters, a second polar sequence of the code having a greater length. The transmitting device may further determine, in accordance with a nesting property of the first polar sequence and at least one of the one or more code parameters, a reordering of extension sequence subchannels. The transmitting device may then encode information using the second polar sequence and transmit the encoded information. In some examples, the transmitting device may further determine localization areas and apply permutation matrices so that extension bit-channels are permuted with bit-channels in the localization areas, thereby preserving bit-channels reliabilities.

A processor (e.g., a standalone chipset or a component of a transmitting device) for wireless communication is described. The processor may be configured to, capable of, or operable to determine, based on a first polar sequence of a code having a first length and one or more code parameters, a second polar sequence of the code having a greater length. The processor may further determine, based on the nesting property of the first polar sequence and at least one of the code parameters, a reordering of extension sequence subchannels. The processor may then cause encoded information to be generated using the second polar sequence and to be transmitted. The processor may additionally determine reliable and noisy bit-channels based on reliability metrics and manage permutation of extension bit-channels within localization areas to improve link performance.

A method performed or performable by a transmitting device for wireless communication is described. The method may include determining, based on a first polar sequence of a code having a first length and one or more code parameters, a second polar sequence of the code having a greater length. The method may further include determining, in accordance with a nesting property of the first polar sequence and at least one of the code parameters, a reordering of extension sequence subchannels. The method may also include transmitting encoded information, wherein the encoded information is encoded using the second polar sequence. In some implementations, the method may include determining localization areas based on bit-channel metrics, applying permutation matrices, and encoding information bits while maintaining ordered channel reliabilities.

### BRIEF DESCRIPTION OF THE DRAWINGS

FIG. 1 illustrates an example of a wireless communications system in accordance with aspects of the present disclosure.

FIG. 2 illustrates an example of an extended polar sequence in accordance with aspects of the present disclosure.

FIG. 3 illustrates another example of an extended polar sequence in accordance with aspects of the present disclosure.

FIG. 4 illustrates an example of a UE in accordance with aspects of the present disclosure.

FIG. 5 illustrates an example of a processor in accordance with aspects of the present disclosure.

FIG. 6 illustrates an example of a NE in accordance with aspects of the present disclosure.

FIG. 7 illustrates a flowchart of a method performed by a transmitting device in accordance with aspects of the present disclosure.

### DETAILED DESCRIPTION

Some wireless communication systems, including those envisioned for 6G and beyond, are expected to meet stringent key performance indicators (KPIs) in terms of spectral efficiency, energy efficiency, user-experienced data rates, and reduced system complexity. To achieve these requirements, additional frequency ranges such as FR3 enable wider bandwidths (e.g., up to 400 MHz) that can support broadband communication, while extra-large multiple-input multiple-output (XL-MIMO) technologies and artificial intelligence/machine learning (AI/ML)-native frameworks act as key enablers for diverse 6G use cases. To sustain these capabilities, enhancements to existing 5G new radio (NR) channel coding schemes are required. Polar codes, used for control channels such as the physical downlink control channel (PDCCH) and physical uplink control channel (PUCCH), offer favorable link performance for small payload sizes and are flexible across different code rates and block lengths without suffering error floors, unlike low-density parity-check (LDPC) or Turbo codes. Polar code construction is founded on the polarization phenomenon, in which bit-channels become either reliable or unreliable as block length grows. Accordingly, polar code design requires identifying sets of reliable bit-channels for carrying information and sets of noisy bit-channels for frozen positions. In 5G NR, the polarization weight method was applied to generate polar reliability sequences for mother block lengths up to 1024 bits (uplink control information (UCI)) and 512 bits (downlink control information (DCI)). However, with the introduction of FR3 bandwidths and XL-MIMO in 6G, UCI/DCI payload sizes will likely grow significantly, requiring new polar code constructions that support larger block sizes, sustain performance at high code rates, and adapt to varying channel conditions while maintaining manageable complexity.

Various aspects of the present disclosure relate to techniques for enhancing polar code construction to satisfy emerging requirements. In particular, there are techniques for designing a polar reliability sequence in a hybrid online/offline manner, wherein part of the sequence is based on a 5G NR polar reliability sequence, and an extended sequence is generated on demand when payload sizes exceed the predefined sequence length. The extension may be determined online based on code block length, signal-to-noise ratio (SNR), or other code parameters, while maintaining the nesting property of the original polar sequence. This partial-order-based design reduces memory overhead to levels comparable to 5G NR while enabling low-computational adaptability when larger payloads must be supported. By generating extensions only when control channel payload sizes (e.g., DCI/UCI) surpass threshold lengths, the scheme balances computational and memory efficiency with performance, enabling robust coding for FR3, XL-MIMO, and AI/ML-driven 6G scenarios.

Aspects of the present disclosure are described in the context of a wireless communications system.

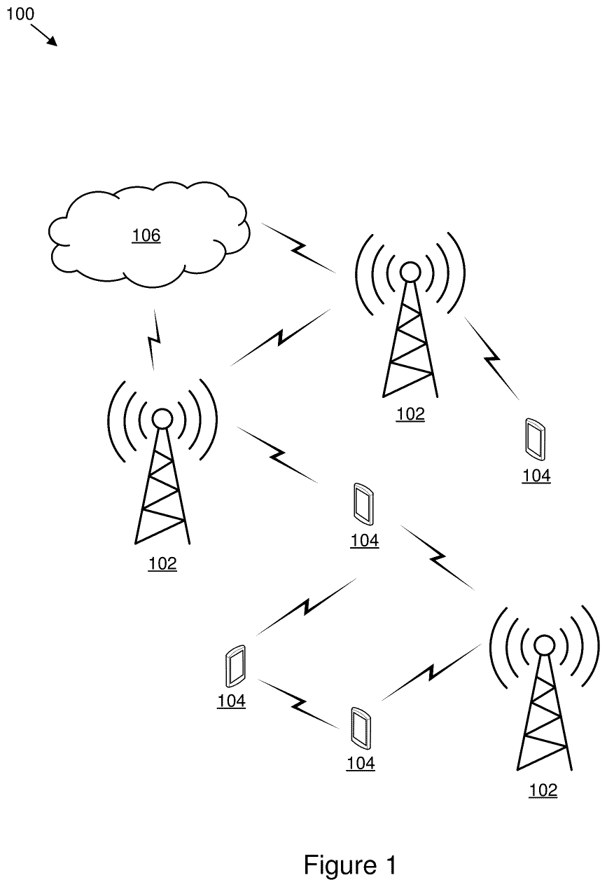

FIG. 1 illustrates an example of a wireless communications system 100 in accordance with aspects of the present disclosure. The wireless communications system 100 may include one or more NE 102, one or more UE 104, and a core network (CN) 106. The wireless communications system 100 may support various radio access technologies. In some implementations, the wireless communications system 100 may be a 4G network, such as an LTE network or an LTE-Advanced (LTE-A) network. In some other implementations, the wireless communications system 100 may be a new radio (NR) network, such as a 5G network, a 5G-Advanced (5G-A) network, or a 5G ultrawideband (5G-UWB) network. In other implementations, the wireless communications system 100 may be a combination of a 4G network and a 5G network, or other suitable radio access technology including Institute of Electrical and Electronics Engineers (IEEE) 802.11 (Wi-Fi), IEEE 802.16 (WiMAX), IEEE 802.20. The wireless communications system 100 may support radio access technologies beyond 5G, for example, 6G. Additionally, the wireless communications system 100 may support technologies, such as time division multiple access (TDMA), frequency division multiple access (FDMA), or code division multiple access (CDMA), etc.

The one or more NE 102 may be dispersed throughout a geographic region to form the wireless communications system 100. One or more of the NE 102 described herein may be or include or may be referred to as a network node, a base station, a network element, a network function, a network entity, a radio access network (RAN), a NodeB, an eNodeB (eNB), a next-generation NodeB (gNB), or other suitable terminology. An NE 102 and a UE 104 may communicate via a communication link, which may be a wireless or wired connection. For example, an NE 102 and a UE 104 may perform wireless communication (e.g., receive signaling, transmit signaling) over a Uu interface.

An NE 102 may provide a geographic coverage area for which the NE 102 may support services for one or more UEs 104 within the geographic coverage area. For example, an NE 102 and a UE 104 may support wireless communication of signals related to services (e.g., voice, video, packet data, messaging, broadcast, etc.) according to one or multiple radio access technologies. In some implementations, an NE 102 may be moveable, for example, a satellite associated with an NTN. In some implementations, different geographic coverage areas associated with the same or different radio access technologies may overlap, but the different geographic coverage areas may be associated with different NE 102.

The one or more UE 104 may be dispersed throughout a geographic region of the wireless communications system 100. A UE 104 may include or may be referred to as a remote unit, a mobile device, a wireless device, a remote device, a subscriber device, a transmitter device, a receiver device, or some other suitable terminology. In some implementations, the UE 104 may be referred to as a unit, a station, a terminal, or a client, among other examples. Additionally, or alternatively, the UE 104 may be referred to as an Internet-of-Things (IoT) device, an Internet-of-Everything (IoE) device, or machine-type communication (MTC) device, among other examples.

A UE 104 may be able to support wireless communication directly with other UEs 104 over a communication link. For example, a UE 104 may support wireless communication directly with another UE 104 over a device-to-device (D2D) communication link. In some implementations, such as vehicle-to-vehicle (V2V) deployments, vehicle-to-everything (V2X) deployments, or cellular-V2X deployments, the communication link may be referred to as a sidelink. For example, a UE 104 may support wireless communication directly with another UE 104 over a UE-to-UE interface (PC5 interface).

An NE 102 may support communications with the CN 106, or with another NE 102, or both. For example, an NE 102 may interface with other NE 102 or the CN 106 through one or more backhaul links (e.g., S1, N2, N3, or network interface). In some implementations, the NE 102 may communicate with each other directly. In some other implementations, the NE 102 may communicate with each other indirectly (e.g., via the CN 106). In some implementations, one or more NE 102 may include subcomponents, such as an access network entity, which may be an example of an access node controller (ANC). An ANC may communicate with the one or more UEs 104 through one or more other access network transmission entities, which may be referred to as a radio heads, smart radio heads, or transmission-reception points (TRPs).

The CN 106 may support user authentication, access authorization, tracking, connectivity, and other access, routing, or mobility functions. The CN 106 may be an evolved packet core (EPC), or a 5G core (5GC), which may include a control plane entity that manages access and mobility (e.g., a mobility management entity (MME), an access and mobility management function (AMF)) and a user plane entity that routes packets or interconnects to external networks (e.g., a serving gateway (S-GW), a Packet Data Network (PDN) gateway (P-GW), or a user plane function (UPF)). In some implementations, the control plane entity may manage non-access stratum (NAS) functions, such as mobility, authentication, and bearer management (e.g., data bearers, signaling bearers, etc.) for the one or more UEs 104 served by the one or more NE 102 associated with the CN 106.

The CN 106 may communicate with a packet data network over one or more backhaul links (e.g., via an S1, N2, N3, N6 or another network interface). The packet data network may include an application server. In some implementations, one or more UEs 104 may communicate with the application server. A UE 104 may establish a session (e.g., a protocol data unit (PDU) session, or the like) with the CN 106 via an NE 102. The CN 106 may route traffic (e.g., control information, data, and the like) between the UE 104 and the application server using the established session (e.g., the established PDU session). The PDU session may be an example of a logical connection between the UE 104 and the CN 106 (e.g., one or more network functions of the CN 106).

In the wireless communications system 100, the NEs 102 and the UEs 104 may use resources of the wireless communications system 100 (e.g., time resources (e.g., symbols, slots, subframes, frames, or the like) or frequency resources (e.g., subcarriers, carriers)) to perform various operations (e.g., wireless communications). In some implementations, the NEs 102 and the UEs 104 may support different resource structures. For example, the NEs 102 and the UEs 104 may support different frame structures. In some implementations, such as in 4G, the NEs 102 and the UEs 104 may support a single frame structure. In some other implementations, such as in 5G and among other suitable radio access technologies, the NEs 102 and the UEs 104 may support various frame structures (i.e., multiple frame structures). The NEs 102 and the UEs 104 may support various frame structures based on one or more numerologies.

One or more numerologies may be supported in the wireless communications system 100, and a numerology may include a subcarrier spacing and a cyclic prefix. A first numerology (e.g., μ=0) may be associated with a first subcarrier spacing (e.g., 15 kHz) and a normal cyclic prefix. In some implementations, the first numerology (e.g., μ=0) associated with the first subcarrier spacing (e.g., 15 kHz) may utilize one slot per subframe. A second numerology (e.g., μ=1) may be associated with a second subcarrier spacing (e.g., 30 kHz) and a normal cyclic prefix. A third numerology (e.g., μ=2) may be associated with a third subcarrier spacing (e.g., 60 kHz) and a normal cyclic prefix or an extended cyclic prefix. A fourth numerology (e.g., μ=3) may be associated with a fourth subcarrier spacing (e.g., 120 kHz) and a normal cyclic prefix. A fifth numerology (e.g., μ=⁴) may be associated with a fifth subcarrier spacing (e.g., 240 kHz) and a normal cyclic prefix.

A time interval of a resource (e.g., a communication resource) may be organized according to frames (also referred to as radio frames). Each frame may have a duration, for example, a 10 millisecond (ms) duration. In some implementations, each frame may include multiple subframes. For example, each frame may include 10 subframes, and each subframe may have a duration, for example, a 1 ms duration. In some implementations, each frame may have the same duration. In some implementations, each subframe of a frame may have the same duration.

Additionally or alternatively, a time interval of a resource (e.g., a communication resource) may be organized according to slots. For example, a subframe may include a number (e.g., quantity) of slots. The number of slots in each subframe may also depend on the one or more numerologies supported in the wireless communications system 100. For instance, the first, second, third, fourth, and fifth numerologies (i.e., μ=0, μ=1, μ=2, μ=3, μ=4) associated with respective subcarrier spacings of 15 kHz, 30 kHz, 60 kHz, 120 kHz, and 240 kHz may utilize a single slot per subframe, two slots per subframe, four slots per subframe, eight slots per subframe, and 16 slots per subframe, respectively. Each slot may include a number (e.g., quantity) of symbols (e.g., OFDM symbols). In some implementations, the number (e.g., quantity) of slots for a subframe may depend on a numerology. For a normal cyclic prefix, a slot may include 14 symbols. For an extended cyclic prefix (e.g., applicable for 60 kHz subcarrier spacing), a slot may include 12 symbols. The relationship between the number of symbols per slot, the number of slots per subframe, and the number of slots per frame for a normal cyclic prefix and an extended cyclic prefix may depend on a numerology. It should be understood that reference to a first numerology (e.g., μ=0) associated with a first subcarrier spacing (e.g., 15 kHz) may be used interchangeably between subframes and slots.

In the wireless communications system 100, an electromagnetic (EM) spectrum may be split, based on frequency or wavelength, into various classes, frequency bands, frequency channels, etc. By way of example, the wireless communications system 100 may support one or multiple operating frequency bands, such as frequency range designations FR1 (410 MHz-7.125 GHz), FR2 (24.25 GHz-52.6 GHz), FR3 (7.125 GHz-24.25 GHz), FR4 (52.6 GHz-114.25 GHz), FR4a or FR4-1 (52.6 GHz-71 GHz), and FR5 (114.25 GHz-300 GHz). In some implementations, the NEs 102 and the UEs 104 may perform wireless communications over one or more of the operating frequency bands. In some implementations, FR1 may be used by the NEs 102 and the UEs 104, among other equipment or devices for cellular communications traffic (e.g., control information, data). In some implementations, FR2 may be used by the NEs 102 and the UEs 104, among other equipment or devices for short-range, high data rate capabilities.

FR1 may be associated with one or multiple numerologies (e.g., at least three numerologies). For example, FR1 may be associated with a first numerology (e.g., μ=0), which includes 15 kHz subcarrier spacing; a second numerology (e.g., μ=1), which includes 30 kHz subcarrier spacing; and a third numerology (e.g., μ=2), which includes 60 kHz subcarrier spacing. FR2 may be associated with one or multiple numerologies (e.g., at least 2 numerologies). For example, FR2 may be associated with a third numerology (e.g., μ=2), which includes 60 kHz subcarrier spacing; and a fourth numerology (e.g., μ=3), which includes 120 kHz subcarrier spacing.

Certain systems may be defined in terms of spectral efficiency, energy efficiency, UE experienced data rates, and overall system complexity. Moreover, frequency bands such as FR3 may enable larger bandwidths (e.g., up to 400 MHz) available for broadband communication, extra-large multiple-input multiple-output (XL MIMO) technologies, and artificial intelligence (AI) and/or machine learning (ML)-native framework.

To enable certain technologies, requirements, and large bandwidths, 5G NR channel coding schemes may be enhanced. In particular, Polar codes may be used for control channels (physical downlink control channel (PDCCH)/physical uplink control channel (PUCCH)) for their link-performance at short-to-moderate payload sizes and for accommodating different code rates and block length sizes without exhibiting an error floor as opposed to low-density parity-check (LDPC) and Turbo codes. Polar code construction may be based on a channel polarization phenomenon, which states that the bit-channels, as the block length tend toward infinity, are either reliable or totally unreliable. In this sense, polar codes construction requires the determination of the set of reliable bit channels that may be associated with information bits and a set of noisy bit-channels may be associated with frozen bits. In 5G NR, a polarization weight method may be used for the generation of a Polar reliability sequence for a mother block length up to 1024 bits (e.g., uplink control information (UCI)) and 512 bits (e.g., downlink control information (DCI)). Since FR3 (e.g., larger bandwidths) and XL-MIMO may induce larger UCI/DCI payload sizes, it may be useful to consider a polar code construction that enables larger code blocks, better performance at high code rates, and better adaptability with varying channel conditions while maintaining acceptable computational and encoding complexity.

Various techniques may be used to result in a polar code reliability sequence in a hybrid online/offline manner, where part of the sequence is a 5G Polar sequence which is nested within a larger sequence that is determined on demand and/or online based on a code block length and given signal-to-noise ratio (SNR) and the rate-matching scheme. This technique may involve a partial order of the polar sequence and may enable low memory overhead with manageable and “on-demand” computational complexity. On-demand may mean that computations for the extension are merely performed when the DCI/UCI mother code lengths exceed the pre-defined polar sequence length.

In some configurations, W: X→Y may denote a generic binary discrete memoryless channel (B-DMC) with input alphabet X, output alphabet Y, and transition probabilities W(y|x), x∈X, y∈Y. The input alphabet X will always be {0,1}, the output alphabet and the transition probabilities may be arbitrary. W_{N} may be used to denote a channel corresponding to N uses of W; thus,

$${X}_{N} \to {Y}_{N} with {W}_{N} ( {y}_{1}^{N} \vert {x}_{1}^{N} ) = {\prod }_{i = 1}^{N} W ( {y}_{i} \vert {x}_{i} ) .$$

Given a B-DMC W, there are two channel parameters of primary interest: the symmetric capacity:

$$I ( W ) = {\sum }_{y ∈ Y} {\sum }_{x ∈ X} \frac{1}{2} W ( y \vert x ) log ( \frac{w ( y \vert x )}{\frac{1}{2} w ( y \vert 0 ) + \frac{1}{2} w ( y \vert 1 )} )$$

and the Bhattacharyya parameter:

Z(W)=Z_{y∈Y}\sqrt{W(y|0)W(y|1)}.

These parameters may be used as measures of rate and reliability, respectively. I(W) is the highest rate at which reliable communication is possible across W using the inputs of W with equal frequency. Z(W) is an upper bound on the probability of maximum-likelihood (ML) decision error when W is used only once to transmit a 0 or 1. It is easy to see that Z(W) takes values in [0,1], whereby a 0 indicates a null probability of error in ML-sense, and respectively, a 1 indicates a certain probability of error in ML-sense.

Channel polarization is an operation by which one manufactures out of N independent copies of a given B-DMC W, a second set of N channels

$$\{ {W}_{N}^{( i )} : 1 \leq i \leq N \}$$

that show a polarization effect in the sense that, as N becomes large, the symmetric capacity terms

$$\{ I ( {W}_{N}^{( i )} ) \}$$

tend towards 0 or 1 for all but a vanishing fraction of indices i. This operation consists of a channel combining phase and a channel splitting phase.
1) Channel combining: This phase combines copies of a given B-DMC W in a recursive manner to produce a vector channel W_{N}:X_{N}→Y_{N}, where N can be any power of two, N=2ⁿ, n≥0. The recursion begins at the 0-th level (n=0) with only one copy of W and we set W₁=W. The first level (n=1) of the recursion combines two independent copies of W₁ and obtains the channel W₂: X₂→Y₂ with the transition probabilities W₂(y₁,y₂|u₁, u₂)=W(y₁|u₁ ⊕u₂) W(y₂|u₂).
2) Channel Splitting: Having synthesized the vector channel W_{N} Out of W^{N}, the next step of channel polarization is to split W_{N} back into a set of N binary-input coordinate channels W_{N}⁽ⁱ⁾:X→Y^{N}×Xⁱ⁻¹, 1≤i≤N, defined by the transition probabilities

$${W}_{N}^{( i )} ( {y}_{1}^{N} , {u}_{1}^{i - 1} \vert {u}_{i} ) {=}^{△} {\sum }_{{u}_{i + 1}^{N} ∈ {X}^{N - i}} \frac{1}{{2}^{N - 1}} {W}_{N} ( {y}_{1}^{N} \vert {u}_{1}^{N} ) ,$$

where

$$( {y}_{1}^{N} , {u}_{1}^{i - 1} )$$

denotes the output of

$${W}_{N}^{( i )}$$

and uᵢ its input. To gain an intuitive understanding of the channels

$$\{ {W}_{N}^{( i )} \} ,$$

consider a genie-aided successive cancellation decoder in which the ith decision element estimates uᵢ after observing

$${y}_{1}^{N}$$

and the past channel inputs

$${u}_{1}^{i - 1}$$

(supplied correctly by the genie regardless of any decision errors at earlier stages). If

$${u}_{1}^{N}$$

is a-priori uniform on X^{N}, then

$${W}_{N}^{( i )}$$

is the effective channel seen by the ith decision element in this scenario.

$$Let F = [ \begin{matrix}1 & 0 \\ 1 & 1\end{matrix} ] ,$$

F^{⊗n} is a N×N matrix known as the Kernel or the polar base matrix, where N=2ⁿ, ⊗n denotes n-th Kronecker power, and F^{⊗n}=F⊗F⊗⁽ⁿ⁻¹⁾. Let the n-bit binary representation of integer i be bₙ₋₁, bₙ₋₂, . . . b₀. The n-bit representation b₀, b₁, . . . , bₙ is a bit-reversal order of i. The generator matrix of polar code is defined as G_{N}=B_{N}F^{⊗n}, where B_{N} is a bit-reversal permutation matrix. The polar code is generated by:

$${x}_{1}^{N} = {u}_{1}^{N} {G}_{N} = {u}_{1}^{N} {B}_{N} {F}^{⊗ n}$$

Where

$${x}_{1}^{N} = ( {x}_{1} , {x}_{2} , … {x}_{N} )$$

is the encoded bit sequence, and

$${u}_{1}^{N} = ( {u}_{1} , {u}_{2} , … {u}_{N} )$$

is the encoding bit sequence. The bit indexes of

$${u}_{1}^{N}$$

divided into two subsets: the one containing the information bits and the other containing the frozen bits. For simplicity, the frozen bits are set “0”.

One main idea of polar codes encoding is the splitting of data sequence indexes into two different sets before transmission. The first set includes the indexes of the data to be transmitted on the noise-free channels. The other set includes the indexes corresponding to the known frozen bits to be transmitted on the pure-noise channel.

Three main techniques may be used for decoding: successive cancellation (SC), successive cancellation list (SCL) and log-likelihood ratio (LLR) based SCL.

As SC decoding may be sub-optimal for finite length polar codes, SCL decoding may be used to achieve the maximum likelihood (ML) bound for a sufficiently large list size L, at the cost of increased complexity due to the list decoding nature. Further enhancement of the code may be conducted via concatenating a high-rate outer code such as Cyclic Redundancy Check (CRC) and parity-check (PC) codes. Under SCL decoding, these CRC-aided polar codes and parity-check concatenated polar codes may outperform the state-of-the-art low-density parity check (LDPC) codes. An extension of polar codes, namely Polar Subcodes may outperform other code constructions. However, the SCL decoder is characterized by a high complexity and an inherently serial decoding nature, which in turn may reduce the decoding throughput and cause high decoding latency. In addition, SCL decoding may not be a good match to iterative detection and decoding due to its hard decision output nature (i.e., not a soft-in/soft-out decoder). Iterative decoding of polar codes based on message passing over the encoding graph has been possible through BP decoders. The BP algorithm may have some fundamental advantages over SC-based decoding, as it can be easily parallelized, thus high throughput/low latency implementations are possible, and it inherently enables soft-in/soft-out decoding, facilitating joint iterative detection and decoding. Thus, BP decoding is a promising candidate for high data rate and low latency demanding applications. A belief propagation list (BPL) decoder with comparable performance to the SCL decoder of polar codes, which already achieves the ML bound of polar codes for sufficiently large list size L.

Code construction may involve determining a code rate (the number of information bits K, or how many sub-channels are to carry information bits) and selecting the particular K sub-channels among the N available sub-channels that are to carry information bits. For ease of reference herein, information bits may include input bits that are to be encoded, and possibly CRC bits, PC bits, and/or other assistant bits that are used to assist in decoding. Sub-channel selection may be based on reliabilities of the sub-channels, and typically the highest reliability sub-channels are selected as information sub-channels for carrying information bits. Sub-channel reliabilities may be specified, for example, in one or more ordered sequences. A single, nested, SNR-independent ordered sequence of sub-channels may be computed for a code length Nmax, with ordered sequences for shorter code lengths N being selected from the longer Nmax sequence. Multiple ordered sequences in terms of different mother code lengths N may instead be computed, and one of the mother code length sequences could be selected for a particular code based on preferred code length. Another possible option involves computing multiple ordered sequences in terms of SNR values, for uplink communications for example, and selecting an ordered sequence based on measured SNR. There are also several methods to compute sub-channel reliabilities.

Ordered sequence computations may be performed online based on observed channel conditions to compute dynamic ordered sequences, offline and in advance to store pre-computed and static ordered sequences for subsequent use in coding, or partially online and partially offline. In certain mobile wireless communications, the radio channel may be time-varying. It may be impractical to consume significant communication bandwidth and processing resources for online sequence computing methods with high computational complexity and latency including genie-aided, density evolution (DE) and Gaussian approximation (GA) based methods. Offline computation of these methods may therefore be used instead, in conjunction with fixing a working SNR or reference SNR for a particular combination of code length and code rate for offline computation of multiple static ordered sequences according to these methods. However, simple online sequence generation methods, or online Polar construction methods, might still be used, in that they generally consume no or much less memory, and may be more flexible and adaptive to time-varying wireless channel conditions.

Among ordered sequences generated by different methods, the ordering of a portion of sub-channels may be the same and only some sub-channels may be ordered differently in different ordered sequences. In the case of a single, nested ordered sequence, the ordering of sub-channels for any code length may be the same as the ordering of those sub-channels for a longer code length. Even for non-nested ordered sequences, only a small number of sub-channels may have a different order between ordered sequences for different code lengths. Partial order-based localization for code construction may avoid the need to calculate relative reliabilities of all sub-channels and instead may involve sorting or re-ordering of only a smaller number of sub-channels within what is referred to herein as a localization area. Such code construction may be adaptive to any rate matching scheme, coding rates, and SNRs while determining a localization area, and/or adaptive to any ordered sequence determination methods within the localization area.

A partial order for the synthesized channels W_{N} (i) of a polar code may be independent of the underlying binary-input channel W. The partial order may be based on the observation that W_{N}(j) is stochastically degraded to W_{N}(i) if j is obtained by swapping a more significant 1 with a less significant 0 in the binary expansion of i.

A channel may be defined as an input alphabet X, an output alphabet Y and transition probabilities ρ_{Y⊕X}(y|x), x∈X,y∈Y. However, channels may naturally arise as pairs of random variables, the input X and the output Y. Thus, this unusual definition of the term channel may be used. A channel with input X and output Y is denoted by X→Y. With this definition, a prior on the input ρ_{X}(x) may be implicitly included in a channel. All channels described herein may be binary-input with a uniform prior on the input.

The following may be used to define channel parameters. Let W be the channel X→Y. The mutual information of W is defined as I(W)=I(X; Y)
and the error probability of W as Pe(W)=P(X≠x\hat{ }(Y))
where \hat{x}(y)=argmax ρ_{X|Y}(x|y) is the maximum a posteriori decision of X given Y.

The following may be used to define stochastic degradation. Let W₁, W₂ be the uniform and binary-input channels X₁→Y₁ and X₂→Y₂, respectively. W₁ is stochastically degraded with respect to W₂, denoted as W₁≤W₂, if probability distributions P(y₁|y₂) exist such that:

$${p}_{Y 1 \vert X 1} ( y 1 \vert x ) = \sum {y}_{2} p ( {y}_{1} \vert {y}_{2} ) {p}_{Y 2 \vert X 2} ( y 2 \vert x ) .$$

The following may be used to define degradation and channel parameters. Let W₁, W₂ be two uniform and binary-input channels. If W₁≤W₂ then I(W1)≤I(W2), Pe(W1)≥Pe(W2).

A permutation on m letters is a bijective mapping from Zm to itself. The permutation matrix of a permutation π on m letters is the unique m×m matrix P with elements in {0, 1} that satisfies: (x0,x1, . . . , xm−1)P=(xπ(0),xπ(1), . . . ,xπ(m−1)).

Various configurations found herein include mechanisms to generate extensions of the polar code sequence using localization method and based on partial ordering theorems of the synthetized channels of polar codes.

A polar sequence may be valid for a mother code length of below 1024 bits for uplink control channels and for a maximum of 512 bits for downlink control channels. This sequence may be determined offline, using methods such as the polarization weight, for a reference SNR known as design-SNR which may make the sequence adapted to different channel conditions. The sequence may be pre-configured and stored at transmitter and receiver devices. An extension to the 5G polar sequence may be computed online (e.g., in real-time) based on one or more code parameters such as a mother code length, a number of information bits, a rate-matching scheme, and/or SNR. This extension may be based on a partial ordering theorem and the determination of the localization area may be computed on-demand when the UCI/DCI payload sizes exceed certain mother code lengths. Depending on a targeted block error rate (BLER) and computational complexity, a final extended polar sequence may approximate bit-channel reliabilities which may facilitate low-complexity computations at the expense of a higher BLER. A more refined polar code sequence for mother code lengths (e.g., larger than 5G NR sequences) may be obtained with more computational resources.

In one configuration, an extension to the 5G NR polar sequence (e.g., of mother code length N) may be determined online based on one or more coding parameters such as targeted mother code length (e.g., N+T), code rate (R), number of information bits (K), rate-matching pattern (Or) and SNR. Based on UCI/DCI payload sizes, a gNB may configure the UE to—or alternatively could—perform computations to determine the reliabilities of the T bit-channels and re-order the resulting bit-channels according to the partial order theorem and the nestedness characteristics of the 5G NR polar code sequence. The reliabilities of the T bit-channels may be determined, according to a first implementation, based on advanced and computationally expensive methods such as density evolution (DE) or Gaussian approximation (GA). In a second implementation, T bit-channels may be reordered in an ascending, or alternatively descending manner, based on beta binary expansion.

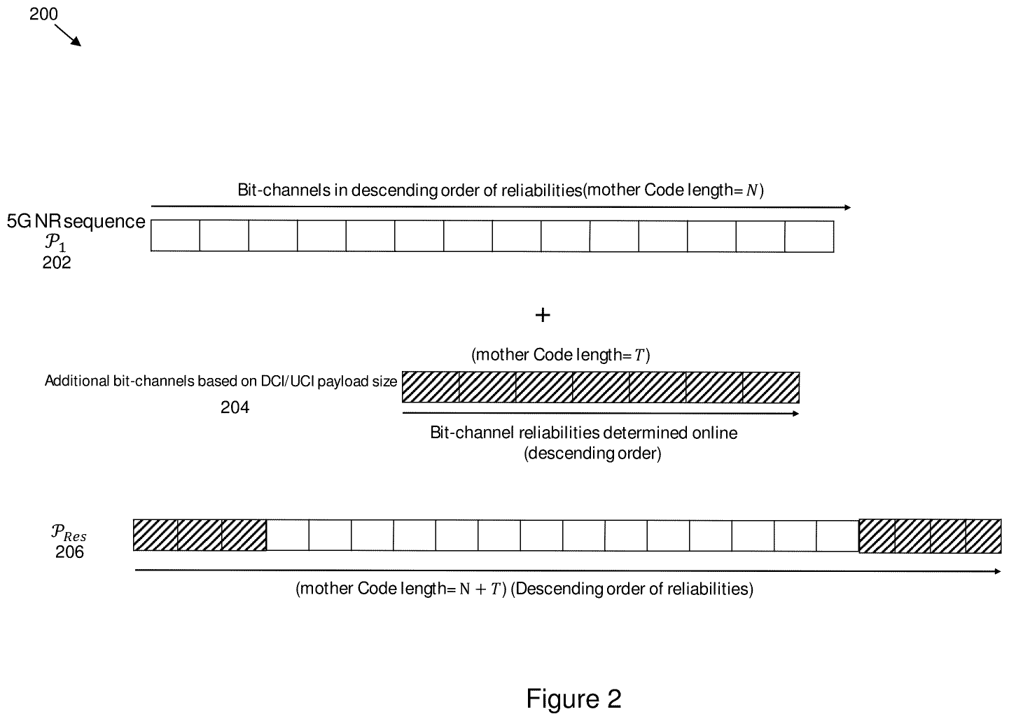

FIG. 2 illustrates an example of an extended polar sequence 200 in accordance with aspects of the present disclosure. The extended polar sequence 200 includes a 5G NR sequence P₁ 202, additional bits 204, and a combined polar sequence [symbol] 206. Specifically, in FIG. 2, the R(N+T) information bits may be associated with the bit-channels with highest order/reliabilities, where RN bits are associated with the first RN bit-channels of the 5G polar sequence defined in an descending order and bounded by a mother code length N (e.g., where the value of N depend on the considered control channel). The remaining RT information bits are determined based on the T bit-channels extension and appended to the 5G NR sequence P₁ 202 such as the bit-channels are appended at the beginning of the polar sequence vector and are associated with highest orders/reliabilities. The remaining bit-channels of the T bit-channels of the polar extension are appended at the end of the 5G NR sequence P₁ 202. The T bit-channels reliabilities may be determined based on the binary expansion and the bit-channels with highest Hamming weight are the bit-channels corresponding to information bits, the bit-channels with lowest Hamming weight may be the bit-channels associated with Frozen bits. The resulting polar code sequence, and the determination of the T bit-channels reliabilities and the appending of the bit-channels in the appropriate places with regards to the 5G NR sequence P₁ 202, is combined polar sequence [symbol] 206 of length (N+K) and where the 5G NR sequence P₁ 202 verifies the nesting property within the combined polar sequence [symbol] 206. This operation requires additional computational complexity of the T bit-channels reliabilities but allows less memory overhead related to the storage of larger polar sequences. The operation is also performed in special cases when the UCI/DCI payload sizes exceed the ones defined in 5G NR; for example, when larger bandwidths are considered e.g., where FR3 or massive/XL MIMO is used.

In another configuration, a polar code extension may be computed in real-time at one of the transmitting or receiving sides and implicitly or explicitly signaled to the other side (e.g., UE/gNB). For example, when UE devices are not adapted to extensive computations, the extension may be performed at the gNB. According to the first implementation, the information bits and frozen bits sets after the extension may be determined by the receiver (e.g., SCL decoder) based on knowledge of the starting 5G NR polar sequence, a nestedness property, a code rate, and a mother code length (N′=R(N+T)). In this case, the received codeword may be in a systematic form, where the associated first R(N+T) bit-channels are the most reliable ones, and the (N−N′) remaining bit-channels are the noisy ones. The receiver may be a list-decoder based on depth-first tree search where frozen bits values are known (usually set to 0 at the transmitter and at the receiver). In another implementation, the computation of the polar sequence extension may be performed by the gNB and explicitly signaled to the UEs (e.g., receiver or transmitter) via RRC signaling. In an alternate implementation, the polar sequence extension may be computed at the gNB and signaled to the UE via RRC signaling and activated/deactivated using DCI signaling depending on one or more code parameters such as mother code length, code rate, and/or rate-matching pattern. In a different configuration, an extended polar sequence verifies the nestedness property and thus polar sequences with any mother block length N_{eff}<N′ may be extracted from the polar sequence of mother block length N′. The resulting polar sequences are approximate solutions to construct polar codes, which might impact link-performance for specific code rates (e.g., high rates).

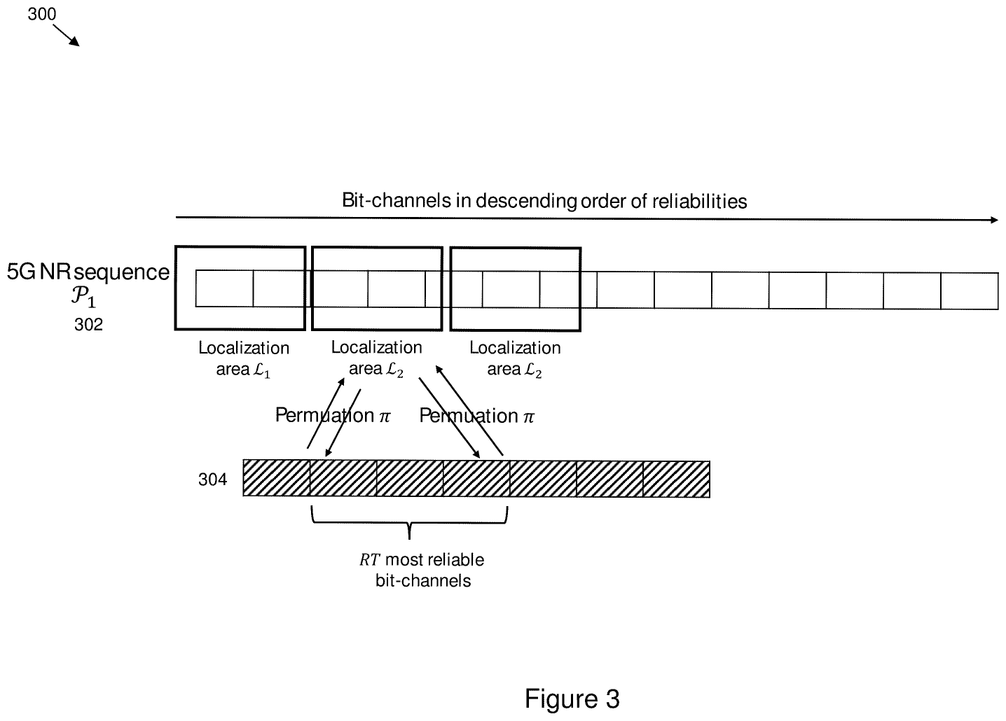

FIG. 3 illustrates another example of an extended polar sequence 300 in accordance with aspects of the present disclosure. The extended polar sequence 300 includes a 5G NR sequence P₁ 302 with additional bits 304 inserted into localization areas. Specifically, in FIG. 3, a fine-tuned polar sequence may be obtained by considering partial re-ordering of the whole polar sequence, in other words, one or more localization areas are determined within the 5G NR polar sequence (e.g., 5G NR sequence P₁ 302) based on one or more code parameters such as code rate, mother code length, number of information bits, rate-matching pattern, and/or SNR. The T-bit channels extension may be re-ordered based on these localization areas. This results in a more fine-tuned and exact polar sequence at the expense of higher computational complexity of the polar code construction. The localization areas may be determined such as they include the set of bit-channels within the set of K-bit channels (where K is the number of information bits of the extended polar sequence), additionally a localization area may include the set of bit-channels above the K-bit channels and the set of bit-channels below the K-bit channels. The re-ordering may then be performed based on a channel degradation definition and/or partial ordering constructions. The metric associated with bit-channels may be the Hamming weight of the binary expansion.

In some configurations, the processing may consider two reliability sequences [symbol] ₁ and [symbol] ₂, where the first sequence of length N and the second sequence is of length T both ordered in ascending, or alternatively in descending, manner. A permutation matrix P_{π} and a bit-significance permutation matrix

$${P}_{π}^{′}$$

are determined based on the degrading channels theorem in the background section. One or more localization areas [symbol] ₁, [symbol] ₂, . . . [symbol] ⱼ are determined within the first sequence based on one or more code parameters such as code rate, mother code length, number of information bits, rate-matching pattern, and/or SNR. In this case, the first bit-channels from the polar sequence [symbol] ₂ are permuted according to the permutation P_{π} with the bit-channels determined in the localization areas [symbol] ₁, [symbol] ₂, . . . [symbol] ⱼ, the remaining bit-channels at the end of the polar sequence [symbol] ₂ are appended at the tail of the polar sequence, ordered in descending manner, after performing permutations. The resulting polar sequence is a larger polar sequence with mother code length N′ and code rate R determined based on link-adaptation techniques and SNR values associated with the time-varying channels.

In a different configuration, the rate-matching scheme may be determined prior to the polar construction, such that rate matching procedures such as puncturing and shortening would not impact the bit-channels reliabilities of the resulting polar sequence [symbol] . Since polar sequence extension is performed in real-time, rate-matching schemes may be considered for the polar code design. According to a first implementation, rate-matching patterns may be determined based on the rate matching pattern of 5G NR and the extension or adaptation of it to larger mother block lengths and different frozen and information bits sets could be done online coupled with polar construction. In a second implementation, one or more rate-matching patterns may be determined and pre-configured based on an offline polar sequence method such as the polarization weight and one or more rate-matching patterns from the set of the rate-matching configurations may be used by the transmitter/encoder based on code parameters and Polar code construction.

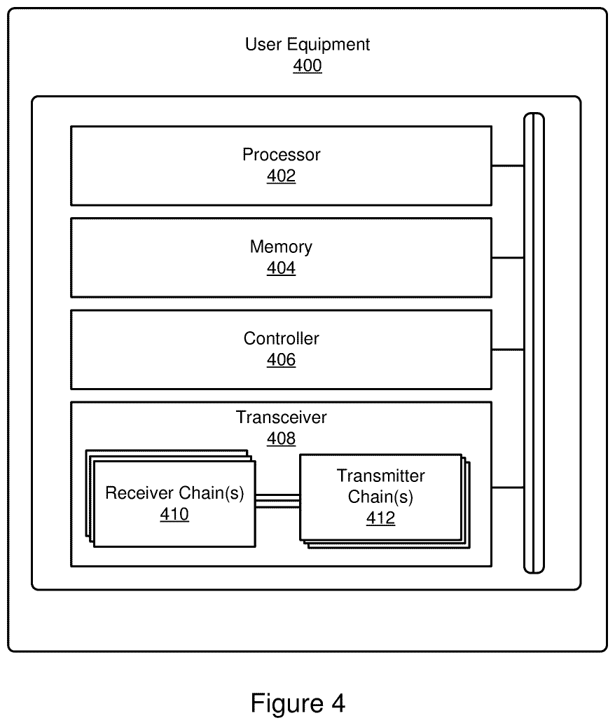

FIG. 4 illustrates an example of a UE 400 in accordance with aspects of the present disclosure. The UE 400 may include a processor 402, a memory 404, a controller 406, and a transceiver 408. The processor 402, the memory 404, the controller 406, or the transceiver 408, or various combinations thereof or various components thereof may be examples of means for performing various aspects of the present disclosure as described herein. These components may be coupled (e.g., operatively, communicatively, functionally, electronically, electrically) via one or more interfaces.

The processor 402, the memory 404, the controller 406, or the transceiver 408, or various combinations or components thereof may be implemented in hardware (e.g., circuitry). The hardware may include a processor, a digital signal processor (DSP), an ASIC, or other programmable logic device, or any combination thereof configured as or otherwise supporting a means for performing the functions described in the present disclosure.

The processor 402 may include an intelligent hardware device (e.g., a general-purpose processor, a DSP, a CPU, an ASIC, a field programmable gate array (FPGA), or any combination thereof). In some implementations, the processor 402 may be configured to operate the memory 404. In some other implementations, the memory 404 may be integrated into the processor 402. The processor 402 may be configured to execute computer-readable instructions stored in the memory 404 to cause the UE 400 to perform various functions of the present disclosure.

The memory 404 may include volatile or non-volatile memory. The memory 404 may store computer-readable, computer-executable code including instructions when executed by the processor 402 cause the UE 400 to perform various functions described herein. The code may be stored in a non-transitory computer-readable medium such the memory 404 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 402 and the memory 404 coupled with the processor 402 may be configured to cause the UE 400 to perform one or more of the functions described herein (e.g., executing, by the processor 402, instructions stored in the memory 404). For example, the processor 402 may support wireless communication at the UE 400 in accordance with examples as disclosed herein. For example, the processor 402 coupled with the memory 404 may be configured to cause the UE 400 to: determine, based on a first polar sequence of a code having a first length and one or more code parameters, a second polar sequence of the code having a second length that is greater than the first length; determine, in accordance with a nesting property of the first polar sequence and at least one of the one or more code parameters, a reordering of extension sequence subchannels; and transmit encoded information, wherein the information is encoded using the second polar sequence.

The controller 406 may manage input and output signals for the UE 400. The controller 406 may also manage peripherals not integrated into the UE 400. In some implementations, the controller 406 may utilize an operating system such as iOS®, ANDROID®, WINDOWS®, or other operating systems. In some implementations, the controller 406 may be implemented as part of the processor 402.

In some implementations, the UE 400 may include at least one transceiver 408. In some other implementations, the UE 400 may have more than one transceiver 408. The transceiver 408 may represent a wireless transceiver. The transceiver 408 may include one or more receiver chains 410, one or more transmitter chains 412, or a combination thereof.

A receiver chain 410 may be configured to receive signals (e.g., control information, data, packets) over a wireless medium. For example, the receiver chain 410 may include one or more antennas for receive the signal over the air or wireless medium. The receiver chain 410 may include at least one amplifier (e.g., a low-noise amplifier (LNA)) configured to amplify the received signal. The receiver chain 410 may include at least one demodulator configured to demodulate the receive signal and obtain the transmitted data by reversing the modulation technique applied during transmission of the signal. The receiver chain 410 may include at least one decoder for decoding the processing the demodulated signal to receive the transmitted data.

A transmitter chain 412 may be configured to generate and transmit signals (e.g., control information, data, packets). The transmitter chain 412 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like PSK or QAM. The transmitter chain 412 may also include at least one power amplifier configured to amplify the modulated signal to an appropriate power level suitable for transmission over the wireless medium. The transmitter chain 412 may also include one or more antennas for transmitting the amplified signal into the air or wireless medium.

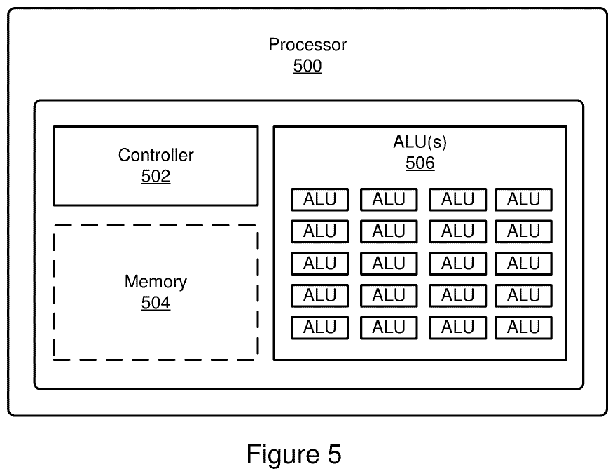

FIG. 5 illustrates an example of a processor 500 in accordance with aspects of the present disclosure. The processor 500 may be an example of a processor configured to perform various operations in accordance with examples as described herein. The processor 500 may include a controller 502 configured to perform various operations in accordance with examples as described herein. The processor 500 may optionally include at least one memory 504, which may be, for example, an L1/L2/L3 cache. Additionally, or alternatively, the processor 500 may optionally include one or more arithmetic-logic units (ALUs) 506. One or more of these components may be in electronic communication or otherwise coupled (e.g., operatively, communicatively, functionally, electronically, electrically) via one or more interfaces (e.g., buses).

The processor 500 may be a processor chipset and include a protocol stack (e.g., a software stack) executed by the processor chipset to perform various operations (e.g., receiving, obtaining, retrieving, transmitting, outputting, forwarding, storing, determining, identifying, accessing, writing, reading) in accordance with examples as described herein. The processor chipset may include one or more cores, one or more caches (e.g., memory local to or included in the processor chipset (e.g., the processor 500) or other memory (e.g., random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), and others).

The controller 502 may be configured to manage and coordinate various operations (e.g., signaling, receiving, obtaining, retrieving, transmitting, outputting, forwarding, storing, determining, identifying, accessing, writing, reading) of the processor 500 to cause the processor 500 to support various operations in accordance with examples as described herein. For example, the controller 502 may operate as a control unit of the processor 500, generating control signals that manage the operation of various components of the processor 500. These control signals include enabling or disabling functional units, selecting data paths, initiating memory access, and coordinating timing of operations.

The controller 502 may be configured to fetch (e.g., obtain, retrieve, receive) instructions from the memory 504 and determine subsequent instruction(s) to be executed to cause the processor 500 to support various operations in accordance with examples as described herein. The controller 502 may be configured to track memory address of instructions associated with the memory 504. The controller 502 may be configured to decode instructions to determine the operation to be performed and the operands involved. For example, the controller 502 may be configured to interpret the instruction and determine control signals to be output to other components of the processor 500 to cause the processor 500 to support various operations in accordance with examples as described herein. Additionally, or alternatively, the controller 502 may be configured to manage flow of data within the processor 500. The controller 502 may be configured to control transfer of data between registers, arithmetic logic units (ALUs), and other functional units of the processor 500.

The memory 504 may include one or more caches (e.g., memory local to or included in the processor 500 or other memory, such RAM, ROM, DRAM, SDRAM, SRAM, MRAM, flash memory, etc. In some implementations, the memory 504 may reside within or on a processor chipset (e.g., local to the processor 500). In some other implementations, the memory 504 may reside external to the processor chipset (e.g., remote to the processor 500).

The memory 504 may store computer-readable, computer-executable code including instructions that, when executed by the processor 500, cause the processor 500 to perform various functions described herein. The code may be stored in a non-transitory computer-readable medium such as system memory or another type of memory. The controller 502 and/or the processor 500 may be configured to execute computer-readable instructions stored in the memory 504 to cause the processor 500 to perform various functions. For example, the processor 500 and/or the controller 502 may be coupled with or to the memory 504, the processor 500, the controller 502, and the memory 504 may be configured to perform various functions described herein. In some examples, the processor 500 may include multiple processors and the memory 504 may include multiple memories. One or more of the multiple processors may be coupled with one or more of the multiple memories, which may, individually or collectively, be configured to perform various functions herein.

The one or more ALUs 506 may be configured to support various operations in accordance with examples as described herein. In some implementations, the one or more ALUs 506 may reside within or on a processor chipset (e.g., the processor 500). In some other implementations, the one or more ALUs 506 may reside external to the processor chipset (e.g., the processor 500). One or more ALUs 506 may perform one or more computations such as addition, subtraction, multiplication, and division on data. For example, one or more ALUs 506 may receive input operands and an operation code, which determines an operation to be executed. One or more ALUs 506 be configured with a variety of logical and arithmetic circuits, including adders, subtractors, shifters, and logic gates, to process and manipulate the data according to the operation. Additionally, or alternatively, the one or more ALUs 506 may support logical operations such as AND, OR, exclusive-OR (XOR), not-OR (NOR), and not-AND (NAND), enabling the one or more ALUs 506 to handle conditional operations, comparisons, and bitwise operations.

The processor 500 may support wireless communication in accordance with examples as disclosed herein. The processor 500 may be configured to or operable to support a means for performing various operations described herein. For example, the processor 500 may be configured to: determine, based on a first polar sequence of a code having a first length and one or more code parameters, a second polar sequence of the code having a second length that is greater than the first length; determine, in accordance with a nesting property of the first polar sequence and at least one of the one or more code parameters, a reordering of extension sequence subchannels; and transmit encoded information, wherein the information is encoded using the second polar sequence.

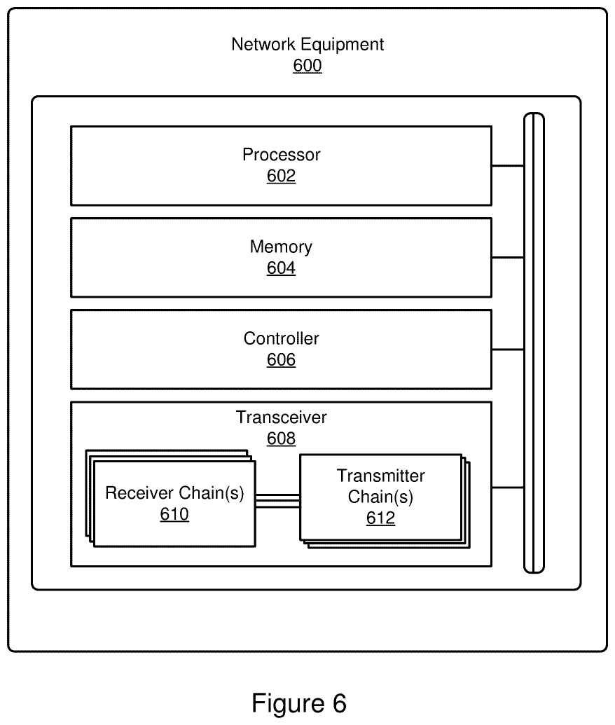

FIG. 6 illustrates an example of an NE 600 in accordance with aspects of the present disclosure. The NE 600 may include a processor 602, a memory 604, a controller 606, and a transceiver 608. The processor 602, the memory 604, the controller 606, or the transceiver 608, or various combinations thereof or various components thereof may be examples of means for performing various aspects of the present disclosure as described herein. These components may be coupled (e.g., operatively, communicatively, functionally, electronically, electrically) via one or more interfaces.

The processor 602, the memory 604, the controller 606, or the transceiver 608, or various combinations or components thereof may be implemented in hardware (e.g., circuitry). The hardware may include a processor, a digital signal processor (DSP), an ASIC, or other programmable logic device, or any combination thereof configured as or otherwise supporting a means for performing the functions described in the present disclosure.

The processor 602 may include an intelligent hardware device (e.g., a general-purpose processor, a DSP, a CPU, an ASIC, an FPGA, or any combination thereof). In some implementations, the processor 602 may be configured to operate the memory 604. In some other implementations, the memory 604 may be integrated into the processor 602. The processor 602 may be configured to execute computer-readable instructions stored in the memory 604 to cause the NE 600 to perform various functions of the present disclosure. For example, the processor 602 coupled with the memory 604 may be configured to cause the NE 600 to: determine, based on a first polar sequence of a code having a first length and one or more code parameters, a second polar sequence of the code having a second length that is greater than the first length; determine, in accordance with a nesting property of the first polar sequence and at least one of the one or more code parameters, a reordering of extension sequence subchannels; and transmit encoded information, wherein the information is encoded using the second polar sequence.

The memory 604 may include volatile or non-volatile memory. The memory 604 may store computer-readable, computer-executable code including instructions when executed by the processor 602 cause the NE 600 to perform various functions described herein. The code may be stored in a non-transitory computer-readable medium such the memory 604 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 602 and the memory 604 coupled with the processor 602 may be configured to cause the NE 600 to perform one or more of the functions described herein (e.g., executing, by the processor 602, instructions stored in the memory 604). For example, the processor 602 may support wireless communication at the NE 600 in accordance with examples as disclosed herein.

The controller 606 may manage input and output signals for the NE 600. The controller 606 may also manage peripherals not integrated into the NE 600. In some implementations, the controller 606 may utilize an operating system such as iOS®, ANDROID®, WINDOWS®, or other operating systems. In some implementations, the controller 606 may be implemented as part of the processor 602.

In some implementations, the NE 600 may include at least one transceiver 608. In some other implementations, the NE 600 may have more than one transceiver 608. The transceiver 608 may represent a wireless transceiver. The transceiver 608 may include one or more receiver chains 610, one or more transmitter chains 612, or a combination thereof.

A receiver chain 610 may be configured to receive signals (e.g., control information, data, packets) over a wireless medium. For example, the receiver chain 610 may include one or more antennas for receive the signal over the air or wireless medium. The receiver chain 610 may include at least one amplifier (e.g., a low-noise amplifier (LNA)) configured to amplify the received signal. The receiver chain 610 may include at least one demodulator configured to demodulate the receive signal and obtain the transmitted data by reversing the modulation technique applied during transmission of the signal. The receiver chain 610 may include at least one decoder for decoding the processing the demodulated signal to receive the transmitted data.

A transmitter chain 612 may be configured to generate and transmit signals (e.g., control information, data, packets). The transmitter chain 612 may include at least one modulator for modulating data onto a carrier signal, preparing the signal for transmission over a wireless medium. The at least one modulator may be configured to support one or more techniques such as AM, FM, or digital modulation schemes like PSK or QAM. The transmitter chain 612 may also include at least one power amplifier configured to amplify the modulated signal to an appropriate power level suitable for transmission over the wireless medium. The transmitter chain 612 may also include one or more antennas for transmitting the amplified signal into the air or wireless medium.

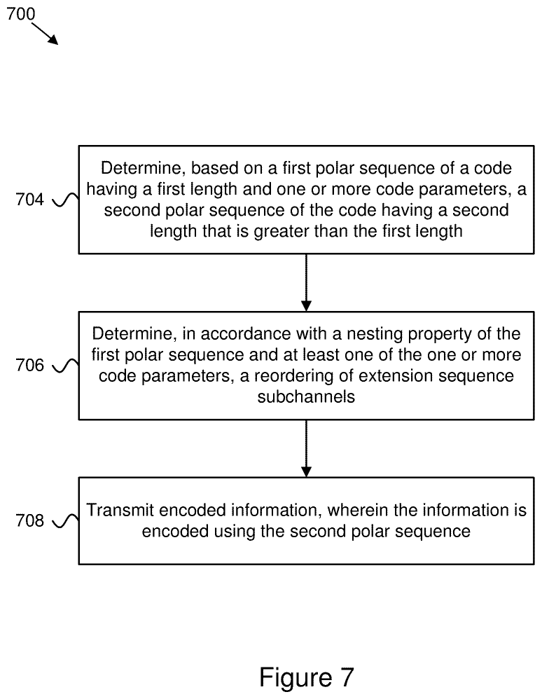

FIG. 7 illustrates a flowchart of a method 700 in accordance with aspects of the present disclosure. The operations of the method 700 may be implemented by a transmitting device (e.g., a UE as described with reference to FIG. 4, an NE as described with reference to FIG. 6). In some implementations, the NE may execute a set of instructions to control the function elements of a processor to perform the described functions. It should be noted that the method described herein describes a possible implementation, and that the operations and the steps may be rearranged or otherwise modified and that other implementations are possible.

At 702, the method may include determining, based on a first polar sequence of a code having a first length and one or more code parameters, a second polar sequence of the code having a second length that is greater than the first length. The operations of 702 may be performed in accordance with examples as described herein. In some implementations, aspects of the operations of 702 may be performed by a UE as described with reference to FIG. 4 and/or an NE as described with reference to FIG. 6.

At 704, the method may include determining, in accordance with a nesting property of the first polar sequence and at least one of the one or more code parameters, a reordering of extension sequence subchannels. The operations of 704 may be performed in accordance with examples as described herein. In some implementations, aspects of the operations of 704 may be performed by a UE as described with reference to FIG. 4 and/or an NE as described with reference to FIG. 6.

At 706, the method may include transmitting encoded information, wherein the information is encoded using the second polar sequence. The operations of 706 may be performed in accordance with examples as described herein. The operations of 706 may be performed in accordance with examples as described herein. In some implementations, aspects of the operations of 706 may be performed by a UE as described with reference to FIG. 4 and/or an NE as described with reference to FIG. 6.

It should be noted that the methods described herein describe possible implementations, and that the operations and the steps may be rearranged or otherwise modified and that other implementations are possible.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A transmitting device, comprising:
at least one memory; and
at least one processor coupled with the at least one memory and configured to cause the transmitting device to:
determine, based on a first polar sequence of a code having a first length and one or more code parameters, a second polar sequence of the code having a second length that is greater than the first length;
determine, in accordance with a nesting property of the first polar sequence and at least one of the one or more code parameters, a reordering of extension sequence subchannels; and
transmit encoded information, wherein the information is encoded using the second polar sequence.

2. The transmitting device of claim 1, wherein the at least one processor is configured to cause the transmitting device to determine, based on bit-channel metrics, one or more localization areas within the first polar sequence and one or more permutation matrices, wherein extension bit-channels are permuted with bit-channels in the one or more localization areas.

3. The transmitting device of claim 2, wherein the at least one processor is configured to cause the transmitting device to determine, based on the second polar sequence, a set of noisy bit-channels associated with frozen bits and one or more sets of reliable bit-channels associated with information bits.

4. The transmitting device of claim 3, wherein the at least one processor is configured to cause the transmitting device to transmit encoded information bits, wherein the information bits are encoded using the second polar sequence.

5. The transmitting device of claim 2, wherein the at least one processor is configured to cause the transmitting device to determine the one or more localization areas by determining a first number of adjacent groups in a partial order above a group to which a Kth bit-channel from a highest end of the partial order belongs and a second number of adjacent groups in a partial order below the group to which a Kth sub-channel from the highest end of the partial order belongs.

6. The transmitting device of claim 1, wherein the one or more code parameters comprise at least one of a code length, a code rate, a rate matching scheme, a number of information bits, or a signal-to-noise ratio (SNR).

7. The transmitting device of claim 1, wherein the second polar sequence is determined based on the one or more code parameters.

8. The transmitting device of claim 1, wherein the second polar sequence is generated in response to a control channel payload size being greater than a threshold size.

9. The transmitting device of claim 1, wherein the nesting property facilitates appending a subset of extension bit-channels at a beginning of the first polar sequence so that a highest end reliability is maintained and a remaining subset of the extension bit-channels to an end of the first polar sequence, wherein the first polar sequence is ordered in a descending manner so that bit channels are ordered from highest to lowest reliabilities with bit channels with highest reliabilities on a left side and bit channels with lowest reliabilities on a right side.

10. The transmitting device of claim 9, wherein highly reliable bit-channels and noisy bit-channels are determined based on one or more bit-channel reliability metrics using high computational methods or moderate-to-low computational methods.

11. The transmitting device of claim 1, wherein the second polar sequence is generated partially offline and partially online, to balance memory usage and computational overhead.

12. The transmitting device of claim 1, wherein a base station performs online extension of the first polar sequence and configures a user equipment (UE) with the second polar sequence via radio resource control (RRC) signaling.

13. The transmitting device of claim 1, wherein a rate matching scheme is determined based on the second polar sequence so that puncturing and shortening does not impact bit-channels reliabilities and overall link-performance of polar codes.

14. The transmitting device of claim 1, wherein the first polar sequence is ordered in an ascending or descending order of reliability.

15. A processor for wireless communication, comprising:
at least one controller coupled with at least one memory and configured to cause the processor to:
determine, based on a first polar sequence of a code having a first length and one or more code parameters, a second polar sequence of the code having a second length that is greater than the first length;
determine, in accordance with a nesting property of the first polar sequence and at least one of the one or more code parameters, a reordering of extension sequence subchannels; and
transmit encoded information, wherein the information is encoded using the second polar sequence.

16. The processor of claim 15, wherein the at least one controller is configured to cause the processor to determine, based on bit-channel metrics, one or more localization areas within the first polar sequence and one or more permutation matrices, wherein extension bit-channels are permuted with bit-channels in the one or more localization areas.

17. The processor of claim 16, wherein the at least one controller is configured to cause the processor to determine, based on the second polar sequence, a set of noisy bit-channels associated with frozen bits and one or more sets of reliable bit-channels associated with information bits.

18. The processor of claim 17, wherein the at least one controller is configured to cause the processor to transmit encoded information bits, wherein the information bits are encoded using the second polar sequence.

19. The processor of claim 16, wherein the at least one controller is configured to cause the processor to determine the one or more localization areas by determining a first number of adjacent groups in a partial order above a group to which a Kth bit-channel from a highest end of the partial order belongs and a second number of adjacent groups in a partial order below the group to which a Kth sub-channel from the highest end of the partial order belongs.

20. A method performed by a transmitting device, the method comprising:
determining, based on a first polar sequence of a code having a first length and one or more code parameters, a second polar sequence of the code having a second length that is greater than the first length;
determining, in accordance with a nesting property of the first polar sequence and at least one of the one or more code parameters, a reordering of extension sequence subchannels; and
transmitting encoded information, wherein the information is encoded using the second polar sequence.
